(19) United States
(12) Patent Application Publication
(10) Pub. No.: US 2004/0224260 A1
(43) Pub. Date: Nov. 11, 2004

(54) Image evaluation method and quality control method for planographic printing plate

(75) Inventors: Mitsuo Osato, Shizuoka-ken (JP); Koichiro Aono, Shizuoka-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 10/834,007

(22) Filed: Apr. 29, 2004

(30) Foreign Application Priority Data
May 8, 2003 (JP) 2003-129756

(51) Int. Cl. G03F 7/00

(52) U.S. Cl. 430/300

(57) ABSTRACT

An image evaluation method of the planographic printing plate comprises the steps of (A) producing a standard developer-treated planographic printing plate by preparing a planographic printing plate precursor comprising a substrate and a photosensitive layer, which includes an aqueous alkaline solution-soluble resin and a compound that absorbs light and generates heat, on the substrate, exposing the planographic printing plate precursor under a condition that forms a checkerboard image of rectangles having one side that is 5 to 50 μm in length, and then developing the image with a standard developer; (B) producing a subject developer-treated planographic printing plate in the same manner as the above-mentioned step (A) except the development is carried out with a subject developer to be evaluated; and (C) comparing the above-mentioned checkerboard images resulted from the standard developer-treated planographic printing plate, with that resulted from the subject developer-treated planographic printing plate.

### CROSS-REFERENCE TO RELATED APPLICATION

This application claims priority under 35 USC 119 from Japanese patent application, No. 2003-129756, the disclosure of which is incorporated by reference herein.

### BACKGROUND OF THE INVENTION

1. Field of the Invention

The present invention relates to an image evaluation method and a quality control method for a planographic printing plate, and more particularly, to an image evaluation method and a quality control method suitable for a positive planographic printing plate for use with an IR laser, which is what is called direct plate-making type, usable for direct plate-making from digital signals of computers or the like.

2. Description of the Related Art

In recent years, laser development has been remarkable. Specifically, a solid state laser and a semiconductor laser having a light emitting region in a range from near IR to an IR region have been developed to have high output and small size. Accordingly, as an exposure light source at the time of direct plate making from digital data of a computer or the like, such lasers are extremely useful.

A positive planographic printing plate precursor for IR laser, for which the above-mentioned IR laser having a light emitting region in the IR region is used as an exposure light source, is aplanographic printing plate precursor (hereinafter, referred to simply as a PS plate in some cases) that comprises an aqueous alkaline solution-soluble binder resin, an IR dye, which absorbs light and generates heat, and the like as essential components.

When the positive planographic printing plate precursor for IR lasers is exposed with an IR laser beam, in non-exposed portions (image portions), the IR dye or the like in the positive planographic printing plate precursor for IR lasers continues to work as a dissolution inhibitor to substantially decrease the solubility of the binder resin, due to the interaction between the IR dye and the binder resin. On the other hand, in exposed portions (non-image portions), the IR dye or the like absorbs light and generates heat, so that the interaction of the IR dye or the like with the binder resin is weakened. Accordingly, at a time of development, the exposed portions (non-image portions) are dissolved in an alkaline developer to produce a planographic printing plate.

However, as compared with a positive planographic printing plate precursor to be used for plate-making by UV exposure, such a positive planographic printing plate precursor for IR lasers has a narrow latitude with respect to the activity of a developer and therefore, has problems wherein if the activity is high, the image part density and printing resistance are decreased and if the activity is low, development failure easily occurs.

The above-mentioned problems are attributed to the following basic differences between the plate-making mechanisms of the above-mentioned positive planographic printing plate material for IR lasers and those of the above-mentioned positive planographic printing plate material for plate-making by UV exposure.

The positive planographic printing plate precursor for plate-making by UV exposure comprises an aqueous alkaline solution-soluble binder resin and an onium salt or quinone diazide compound as essential components. When such a positive planographic printing plate precursor is exposed, the onium salt or quinone diazide compound works in the non-exposed portions (image portions) as a dissolution inhibitor similar to the case of the positive planographic printing plate precursor for IR lasers. However, unlike the case of the positive planographic printing plate precursor for IR lasers, in the exposed portions (non-image portions), it is decomposed by light, and generates an acid, and consequently works as a dissolution promoting agent for the binder resin. Accordingly, in the positive planographic printing plate precursor for plate making by UV exposure, the difference of the solubility with respect to an alkaline developer between the exposed portions and the non-exposed portions is very large.

In contrast, with respect to the positive planographic printing plate precursor for IR lasers, although the interaction between the IR dye and the binder resin is weakened in the exposed portions (non-image portions) at a time of exposure, the IR dye does not work as the dissolution promoting agent for the binder and therefore, the difference of the solubility between the non-exposed parts and the exposed parts is small.

Due to the above-mentioned reasons, when a planographic printing plate precursor such as a positive planographic printing plate precursor for IR laser having a narrow latitude to the activity of a developer is used, it is very difficult to control the plate making process to continuously form stable images.

Generally, in the case of developing the positive planographic printing plate precursor for IR lasers, an automatic developing apparatus having a replenishing mechanism for keeping the developer sensitivity constant as much as possible is employed. The replenishing mechanism is for adding a highly active replenishing solution so as to prevent pH decrease and deterioration of the developability of the developer due to developing of the plates or CO₂ absorption.

Practically, in a treatment system for a regular PS plate, i) a conductivity-controlling method of adding a replenishing solution so as to keep conductivity constant (See Japanese Patent Application Laid-Open (JP-A) No. 8-44076 and Japanese Patent Publication Nos. 5-8823, 6-3542, and 6-12435) and ii) a method of adding a predetermined amount of a replenishing solution periodically after the number of sheets developed by a planographic printing plate precursor reaches a predetermined number or after a predetermined treatment time passes (See JP-A Nos. 2000-105465 and 6-43661) have been proposed.

However, in i), i.e., in the method for controlling a replenishing solution based on the conductivity, there arises a problem in that pH values vary (thus developability also changes), even at the same conductivity, between the starting time of development and a later stage, because significantly amounts of compositions of a photosensitive layer are dissolved into the developer as the number of the developed sheets increases.

Further, in ii), i.e., in the method of periodically adding a predetermined amount of the replenishing solution, as the amount of the (applied) replenishing solution per unit surface area of a plate is fixed, the method cannot address to changes such as: the amount of compositions of the photosensitive layer dissolved into a developer varying in accordance with the area of image portions; and the CO₂ absorption amount changing over time depending on the installation environment (temperature, humidity, CO₂ concentration and the like) of the automatic developing apparatus. Thus, it is difficult to continuously keep the constant developability by controlling with such a method of periodically adding a predetermined amount of the replenishing solution.

Generally, in a widely used planographic printing plate precursor using UV exposure, since the precursor has a wide latitude with respect to the activity of a developer, the fluctuation of the developability as described above is not a major problem. However, as described above, since the positive planographic printing plate precursor for IR lasers has a narrow latitude with respect to the activity of the developer, the image formability, especially the dot formability, fluctuates considerably depending on changes in the activity of the developer, which results in problems regarding quality of the planographic printing plate.

Further, recently, demands to obtain highly precise images have been increasing. For example, image formability with a resolution as high as 1,000 to 4,000 dpi is required for practical application. In order to satisfy such requirements, the image formability in fine parts (dot formability) has to be stabilized further. Accordingly, as described above, the fluctuation of the image formability due to activity changes of the developer in the positive planographic printing plate precursor for IR lasers has become a more and more serious issue than ever before. Therefore, it is urgently desired in present situation to establish an image evaluation method for evaluating the image formability in a planographic printing plate and also a quality control method for keeping the image formability constant.

### SUMMARY OF THE INVENTION

The present invention aims to solve the above-mentioned problems and accomplish the following aims.

That is, a first object of the invention is to provide a simple image evaluation method of a planographic printing plate for easily determining the plate-making conditions, especially, the active state of a developer, of a positive planographic printing plate precursor for IR lasers for use in direct plate-making.

A second object of the invention is to provide a quality control method of a planographic printing plate precursor for continuously forming uniform images even when highly precise images are to be formed by keeping the quality of the planographic printing plate by carrying out feed-back of the results obtained by the above-mentioned image evaluation method to the exposure/development process.

As a result of keen study, the inventors of the present invention have found that the formed images can easily be evaluated by comparing a planographic printing plate precursor which is exposed under specific conditions and then subjected to plate-making process under standardized conditions with a similar planographic printing plate precursor that is subjected to plate-making process under conditions to be evaluated and that the quality control of a planographic printing plate can easily carried out by using feed back from the evaluation results.

That is, in a first aspect of the present invention, an image evaluation method of the planographic printing plate comprises the steps of (A) producing a standard developer-treated planographic printing plate by preparing a planographic printing plate precursor (hereinafter, simply referred to as specific planographic printing plate precursor in some cases) comprising a substrate and a photosensitive layer, which includes an aqueous alkaline solution-soluble resin and a compound that absorbs light and generates heat, the photosensitive layer being provided on the substrate, exposing the planographic printing plate precursor under a condition that forms a checkerboard image of rectangles having one side that is 5 to 50 μm in length, and then developing the image with a standard developer; (B) producing a subject developer-treated planographic printing plate in the same manner as the above-mentioned step (A) except the development is carried out with a subject developer to be evaluated; and (C) comparing the above-mentioned checkerboard images resulted from the standard developer-treated planographic printing plate, with that resulted from the subject developer-treated planographic printing plate.

In a second aspect of the present invention, a quality control method of a planographic printing plate comprises the steps of (A) producing a standard developer-treated planographic printing plate by preparing a planographic printing plate precursor having a substrate and a photosensitive layer, which includes an aqueous alkaline solution-soluble resin and a compound that absorbs light and generates heat, disposed on the substrate, exposing the planographic printing plate precursor under conditions that forms a checkerboard image composed of rectangles having one side which is 5 to 50 μm in length, and then developing the image with a standard developer; (B) producing a subject developer-treated planographic printing plate in the same manner as in the above-mentioned step (A) except that the development is carried out with a subject developer to be evaluated; (C) comparing the above-mentioned checkerboard images resulted from the standard developer-treated planographic printing plate, with that resulted from the subject developer-treated planographic printing plate; and (D) adjusting the exposure/development conditions, when a difference between the density of the above-mentioned checkerboard image resulted from the standard developer-treated planographic printing plate and the density of the checkboard image of the subject developer-treated planographic printing plate is confirmed to be at least a predetermined value, based on the result of the comparison.

The quality control method for a planographic printing plate of the invention may further comprise the step of (E) producing a planographic printing plate in a manner similar to that of the step (B) but under adjusted exposure/development conditions after completing the step (D), and the steps (E), (C), and (D) are preferably carried out in this order one time or multiple times.

### DESCRIPTION OF THE PREFERRED EMBODIMENTS

Hereinafter, an image evaluation method for a planographic printing plate of the present invention (hereinafter, occasionally referred to as an image evaluation method) and a quality control method for aplanographic printing plate of the invention (hereinafter, occasionally referred to as a quality control method) will be described in detail.

### Image Evaluation Method of Planographic Printing Plate

The image evaluation method of the invention comprises the above-mentioned steps (A) to (C). Hereinafter, the respective steps of the invention will be described successively.

First, in step (A), a standard developer-treated planographic printing plate is produced by exposing a specific planographic printing plate precursor under conditions that form a checkerboard image of rectangles having one side that is 5 to 50 μm in length (hereinafter, which checkboard image will simply referred to as “checker image” in some cases), and then developing the image with a standard developer (a developer with a standard composition).

The rectangles composing the above-mentioned checker pattern are required to have one side that is 5 to 50 μm in length. The length of the one side is properly determined within the above-mentioned range, depending on the quality required for the image to be formed on a planographic printing plate precursor.

In the invention, “a checkerboard image of rectangles having one side that is 5 to 50 μm in length (a checker image)” means a region formed by rectangles of exposed or unexposed portions with a size in the predetermined range arranged alternately in a checkerboard pattern. Further, the length of the one side of the rectangles composing the checker image is the length of one side of a minimum pixel unit (1 pixel width) The rectangles composing the checker pattern are normally squares, however they are not limited to this.

The checker image in step (A) may be formed in a part of the surface of a single specific planographic printing plate precursor, for example, about 20% of the surface area or may be formed partially in a plurality of parts. The size of one side of the image formation region is preferably at least 7 mm in consideration of the minimum measurable surface area for a densitometer.

The produced standard developer-treated planographic printing plate is to be a standard specimen for basic development conditions and the developer preparation manner, treatment duration, and treatment temperature employed in this case are used as standard processes. Incidentally, it is not necessary to produce the standard developer-treated planographic printing plate to be an evaluation standard every time the evaluation is performed and only one planographic printing plate need be produced in an initial step if evaluation and control are performed in continuous steps of carrying out single plate-making process.

Next, a subject developer-treated planographic printing plate is produced in step (B).

The subject developer-treated planographic printing plate to be produced in this step is for confirming the fatigue state of a developer after of time lapses. When the evaluation is required, the planographic printing plate is obtained by treating a specific planographic printing plate precursor similar to that used for producing the standard developer-treated planographic printing plate in step (A). In this case, with respect to the development temperature and treatment duration, the same conditions as those employed in the production of the standard developer-treated planographic printing plate in step (A) are used.

Next, in step (C), the density of the checkerboard image in the standard developer-treated planographic printing plate is compared with that in the subject developer-treated planographic printing plate. The change in activity of a developer can easily be detected based on the result of the comparison of the standard developer-treated planographic printing plate produced in the plate-making conditions in step (A) and the subject developer-treated planographic printing plate produced under the plate-making conditions in step (B). Accordingly, whether exposure/development conditions should be adjusted or not can be judged.

In the invention, when an apparatus independently produces a planographic printing plate precursor on which the checker image is to be formed and subjects the planographic printing plate precursor to a common plate-making process, the image evaluation and the quality control of the planographic printing plate, which will be described later, can be carried out at the apparatus by placing the thus obtained planographic printing plate precursor between other planographic printing plate precursors at a predetermined interval and observing the plate-making state of the planographic printing plate precursor obtained by the invention and other precursors. Alternatively, the image evaluation and the quality control of the planographic printing plate can be carried out by forming a checker image in a margin portion of a planographic printing plate precursor produced by the plate-making process, which margin portion is a frame portion of the planographic printing plate precursor, and observing the plate-making state of the printing plate.

### Quality Control Method of Planographic Printing Plate

The quality control method of the invention provides a method comprising a step [step (D)] of adjusting the exposure/development conditions, when a difference between the density of the above-mentioned checkerboard image resulted from the standard developer-treated planographic printing plate and the density of the checkerboard image resulted from the subject developer-treated planographic printing plate is turned out to be at least a predetermined value based on the result of the comparison by the above-mentioned image evaluation method involving with steps (A) to (C). That is, the quality control method of the invention is a method for rationally controlling the quality of a planographic printing plate by adjusting the exposure step/the development step on the basis of the feedback from the evaluation result obtained by the image evaluation method of the invention.

When the exposure/development step is adjusted on the basis of the feedback of the predetermined value in step (D), the density difference to be a criterion for the above-mentioned adjustment may properly be determined depending on the quality required for the planographic printing plate. In general, when the density difference of the checkerboard image in the standard developer-treated planographic printing plate (a standard sample) and that is the subject developer-treated planographic printing plate becomes 0.1 or higher, the alteration of the image formability can be detected with eye observation based on a comparison of a pair of planographic printing plates and therefore such a value can be a criterion for feedback to the exposure/development step.

The an image density values in this specification were measured using a reflection type densitometer (D19C model) manufactured by GRETAG Inc.

Means for adjusting the exposure/development condition in step (D) is as follows.

When developability deterioration is observed in an evaluated subject developer-treated planographic printing plate, namely, when the density of the checkerboard image is increased, it is acceptable either the exposure condition is to be increased or for the development condition to be activated. Also, when development is carried out too far, that is the density of the checkerboard image is decreased, it is acceptable for either the exposure condition to be lowered or for the development condition to be moderated.

The following are means for the counteracting the case in which the density difference of the checkerboard images reaches a predetermined value or higher due to excessive development.

<Means to be Employed for Adjustment in the Development Step>

(1) Adding water to the developer.

(2) Adding dry ice to the developer.

(3) Blowing C0₂ gas in.

(4) Decreasing the dilution ratio of the replenishing solution.

(5) Lessening the set amount of the replenishing solution (to be replenished) of the automatic developing apparatus.

(6) Decreasing the development temperature.

(7) Shortening the development duration (increasing the

transportation speed of the automatic developing apparatus).

(8) Decreasing the pressure of developing brushes of the automatic developing apparatus.

(9) Lessening the number of the developing brushes of the automatic developing apparatus.

(10) Decreasing the spraying amount.

(11) Stirring the developer.

(12) Replacing the developer with a new developer. ps <Means to be Employed for Adjustment in the Exposure Step>

(13) Decreasing the exposure extent.

(14) Heating the positive planographic printing plate precursor for IR lasers before exposure.

The following are means for counteracting the case in which the density difference of the checkerboard images reaches a predetermined value or higher due to deterioration of the developability.

<Means to be Employed for Adjustment in the Development Step>

(1) Adding the replenishing solution.

(2) Increasing the dilution ratio of the replenishing solution.

(3) Increasing the set amount of the replenishing solution (to be replenished) of the automatic developing apparatus.

(4) Increasing the development temperature.

(5) Lengthening the development duration (decreasing the transportation speed of the automatic developing apparatus).

(6) Increasing the pressure of developing brushes of the automatic developing apparatus.

(7) Increasing the number of the developing brushes of the automatic developing apparatus.

(8) Increasing the spraying amount.

(9) Replacing the developer with a new developer.

<Means to be Employed for Adjustment in the Exposure Step>

(10) Increasing the exposure extent.

In the case in which the exposure extent is controlled by the above-mentioned adjustment means, conditions such as the output of laser beam, beam diameter, scanning speed, and exposure duration may properly be adjusted.

In the quality control method of the invention, the method preferably further includes, after completing steps (A) to (D), the step (E) of producing a subject developer-treated planographic printing plate in a manner similar to that of the step (B) but under the adjusted exposure/development conditions. It is preferable that the steps (E), (C), and (D) be carried out in this order once or a plurality of times.

In this manner, by repeating the feedback of the result of the image evaluation to the exposure/development conditions, the development state of the planographic printing plate can be kept stable for a long duration.

### Planographic Printing Plate Precursor

Hereinafter, a planographic printing plate precursor to be subjected to the image evaluation method and quality control method of the invention will be described in detail.

The planographic printing plate precursor relevant to the invention is not particularly limited as long as it comprises a photosensitive layer containing an aqueous alkaline solution-soluble resin and a compound which absorbs light and generating heat on a substrate. The photosensitive layer is required to essentially contain an aqueous alkaline solution-soluble resin and a compound which absorbs light and generates heat and may further contain additionally additives commonly used for a positive type photosensitive composition for IR laser.

(Photosensitive Layer)

<Aqueous Alkaline Solution-soluble Resin>

As the aqueous alkaline solution-soluble resin relevant to the invention include homopolymers having an acidic group in the polymer main chain and/or side chain, their copolymers, and their mixtures. Among them, those having the following acidic groups (1) to (6) in the polymer main chain and/or side chain are preferable in terms of solubility in an alkaline developer and dissolution suppressing function.

(1) Phenol group (—Ar—OH).

(2) Sulfonamide group (—SO₂NH—R).

(3) Substituted sulfonamide type acid group (hereinafter, referred to as activated imide group) [—SO₂NHCOR, —SO₂NHSO₂R, —CONHSO₂R].

(4) Carboxylic acid group (—CO₂H).

(5) Sulfonic acid group (—SO₃H).

(6) Phosphoric acid group (—OPO₃H₂).

In the above-exemplified (1) to (6), Ar denotes a substituted/unsubstituted divalent aryl bonding group and R denotes a substituted/unsubstituted hydrocarbon group.

Among aqueous alkaline solution-soluble resins having an acidic group selected from the groups (1) to (6), aqueous alkaline solution-soluble resins having (1) phenol group, (2) sulfonamide group, and (3) activated imide group are preferable; aqueous alkaline solution-soluble resins having (1) phenol group and (2) sulfonamide group are more preferable in terms of the solubility in the alkaline developer, development latitude, and sufficient retention of film strength; and an aqueous alkaline solution-soluble resins having (1) phenol group is most preferable.

Examples of the aqueous alkaline solution-soluble resin having the acidic group selected from the above-mentioned (1) to (6) are as follows.

(1) Examples of the aqueous alkaline solution-soluble resin having phenol group are novolak resins such as condensation polymers of phenol and formaldehyde, condensation polymers of m-cresol and formaldehyde, condensation polymers of p-cresol and formaldehyde, condensation polymers of m-/p-mixed cresol and formaldehyde, and condensation polymers of phenol, cresol (m-, p-, or mixture of m-/p-isomers), and formaldehyde; and condensation polymers of pyrogallol and acetone. Further, copolymers obtained by copolymerization of compounds having phenol group in the side chains are also exemplified. Or, copolymers obtained by copolymerization of compounds having phenol group in the side chains are also usable.

As the compounds having phenol group, acrylamide, methacrylamide, acrylic acid esters, methacrylic acid esters, or hydroxysythrene having phenol group can be exemplified. (2) Examples of the aqueous alkaline solution-soluble resin having sulfonamido group is polymers comprising minimum monomer units derived from compounds having sulfoneamido group as main constituent components. Examples of such compounds are compounds having sulfoneamido group comprising nitrogen atom and at least one hydrogen atom bonded to the nitrogen atom and a polymerizable unsaturated group respectively in one molecule. Above all, low molecular weight compounds having acryloyl group, allyl group, or vinyloxy group as well as substituted or mono-substituted aminosulfonyl group or substituted sulfonylimino group in one molecule are preferable and practical examples are those defined by the following general formulas (i) to (v).

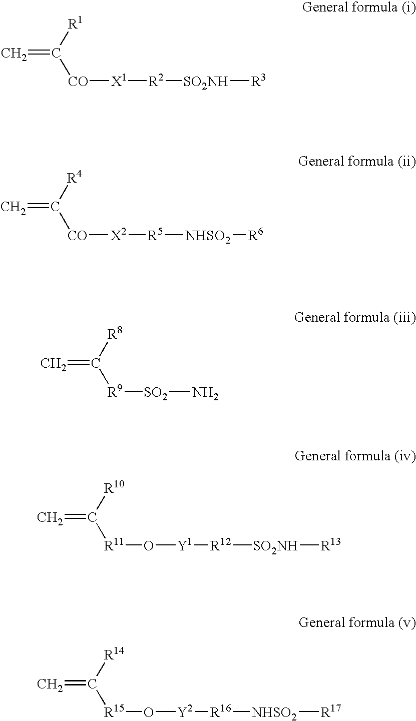

In the formula X¹ and X² independently denote —O— or NR⁷; R¹ and R⁴ independently denote hydrogen, or —CH₃; R², R⁵, R⁹, R¹² and R¹⁶ independently denote substituted/unsubstituted C₁₋₁₂ alkylene group, cycloalkylene group, arylene group, or aralkylene group; R³, R⁷, and R¹³ independently denote hydrogen, substituted/unsubstituted C₁₋₁₂ alkyl group, cycloalkyl group, aryl group, or aralkyl group; R⁶ and R¹⁷ independently denote substituted/unsubstituted C₁₋₁₂ alkyl group, cycloalkyl group, aryl group, or aralkyl group; R⁸, R¹⁰, and R¹⁴ independently denote hydrogen or —CH₃; R¹¹ and R¹⁵ independently denote C₁₋₁₂ alkylene group, cycloalkylene group, arylene group, or aralkylene group optionally having single bond or a substituent group; and Y¹ and Y² independently denote a single bond or CO.

Among the compounds defined by the general formula (i) to (v), for the planographic printing plate precursor of the invention, m-aminosulfonylphenyl methacrylate, N-(p-aminosulfonylphenyl) methacrylamide, and N-(p-aminosulfonylphenyl) acrylamide are especially preferably used.

(3) Examples of the aqueous alkaline solution-soluble resin having activated imido group is polymers comprising minimum monomer units derived from compounds having activated imido group as main constituent components. Examples of such compounds are compounds having activated imido groups and polymerizable unsaturated groups at least one each in one molecule defined by the following structural formula.

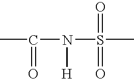

Practically, N-(p-toluenesulfonyl) methacrylamide, and N-(p-toluenesulfonyl) acrylamide are especially preferably used.

(4) Examples of the aqueous alkaline solution-soluble resin having carboxylic acid group are polymers comprising minimum monomer units derived from compounds having carboxylic acid groups and polymerizable unsaturated groups at least one each in one molecule as main constituent components.

(5) Examples of the alkali-soluble polymers having sulfonic acid group are polymers comprising minimum monomer units derived from compounds having sulfonic acid groups and polymerizable unsaturated groups at least one each in one molecule as main constituent components.

(6) Examples of the aqueous alkaline solution-soluble resin having phosphoric acid group are polymers comprising minimum monomer units derived from compounds having phosphoric acid groups and polymerizable unsaturated groups at least one each in one molecule as main constituent components.

The minimum monomer units having acidic groups selected from above-mentioned (1) to (6) which compose the above-mentioned aqueous alkaline solution-soluble resin are not necessarily only one type but copolymers obtained by copolymerization of two or more types of the minimum monomer units having the same acidic group or two or more types of the minimum monomer units having different acidic groups may be used.

The copolymers are those containing preferably at least 10% by mole, more preferably at least 20% by mole, of the compounds having the acidic groups selected from the above-mentioned (1) to (6) in them. If it is less than 10% by mole, the development latitude tends to be improved insufficiently.

In the invention, in the case of using copolymers obtained by copolymerization of the compounds as the aqueous alkaline solution-soluble resin, as the compounds to be copolymerized, compounds other than those having the acidic groups selected from the above-mentioned (1) to (6) may be used.

As the aqueous alkaline solution-soluble resin, resins having phenolic hydroxyl group are preferable because of excellent image formability by exposure by IR laser and preferable examples are novolak resins such as phenol formaldehyde resin, m-cresol formaldehyde resin, p-cresol formaldehyde resin, m-/p-mixed cresol formaldehyde resin, phenol/cresol (m-, p-, or mixture of m-/p-isomers), and mixed formaldehyde resin and pyrogallol acetone resin

Also, examples of the aqueous alkaline solution-soluble resin having phenolic hydroxyl group may further include, as described in U.S. Pat. No. 4,123,279, condensation polymers of phenol having C₃₋₈, alkyl group as a substituent and formaldehyde such as tert-butylphenol formaldehyde resin, octylphenol formaldehyde resin and aqueous alkaline solution-soluble resin having phenol structure containing electron attractive group in an aromatic ring as described in JP-A No. 2000-241972.

In the invention, among these aqueous alkaline solution-soluble resins having phenolic hydroxyl group, in terms of coating characteristics, condensation polymers comprising phenols such as o-cresol, m-cresol, p-cresol, 2,5-xylenol, 3,5-xylenol, and resorcinol and either aldehyde or ketone such as formaldehyde, acetaldehyde, and propionaldehyde are preferable and especially, condensation polymers comprising either a phenol mixture containing m-cresol, p-cresol, 2,5-xylenol, 3,5-xylenol, and resorcinol at a ratio of (40 to 100):(0 to 50):(0 to 20):(0 to 20):(0 to 20) by mole or a phenol mixture containing phenol, m-cresol, and p-cresol at a ratio of (0 to 100):(1 to 70):(1 to 60) and formaldehyde are further preferable.

The weight average molecular weight of the aqueous alkaline solution-soluble resin is preferably 500 or higher, morepreferablyl,000 to 700,000, in terms of image formability. The number average molecular weight of it is preferably 500 or higher, more preferably 750 to 650,000. The dispersion (weight average molecular weight/number average molecular weight) is preferably 1.1 to 10.

The total content of the aqueous alkaline solution-soluble resin in the invention is preferably 30 to 99% by mass, more preferably 40 to 95% by mass, in the total solid matters in the photosensitive layer, in terms of durability, sensitivity, and image formability.

<Compound Absorbing Light and Generating Heat>

As a compound absorbing light and generating heat relevant to the invention, any substance can be used without any particular limitation of absorption wavelength if the substance can absorb photoenergy radiation beam to be used for recording and thereby generates heat. In terms of applicability to easily available high output laser, IR-absorbing dyes or pigments having the absorption maximum at wavelength of 760 nm to 1,200 nm are preferable.

As the dyes, commercialized dyes, for example, well known dyes described in documents such as “Dye Handbook” (Organic Synthetic Chemical Assoc., 1970) can be employed. Practical examples are azo dyes, metal complex azo dyes, pyrazolone azo dyes, naphthoquinone dyes, anthraquinone dyes, phthalocyanine dyes, carbonium dyes, quinonimine dyes, methine dyes, cyanine dyes, squaryliumdyes, pyrylliumdyes, metal thiolate complexes, oxonol dyes, diiminium dyes, aminium dyes, and croconium dyes.

Preferable dyes are, for example, cyanine dyes described in JP-A Nos. 58-125246, 59-84356, 59-202829, and 60-78787; methine dyes described in JP-A Nos. 58-173696, 58-181690, and 58-194595; naphthoquinone dyes described in JP-A Nos. 58-112793, 58-224793, 59-48187, 59-73996, 60-52940, and 60-63744; squarylium dyes described in JP-A No. 58-112792; and cyanine dyes described U.K. Patent NO. 434,875.

Near IR absorbing sensitizing agents described in U.S. Pat. No. 5,156,938 are also usable and further, substituted aryl benzo (thio) pyryllium salts described in U.S. Pat. No. 3,881,924; trimethine thiapyryllium salts described in JP-A No. 57-142645 (U.S. Pat. No. 4,327,169); pyryllium type compounds described in JP-A Nos. 58-181051, 58-220143, 59-41363, 59-84248, 59-84249, 59-146063, and 59-146061; cyanine dyes described in JP-A No. 59-216146; pentamethine thiopyryllium salts described in U.S. Pat. No. 4,283,475; and pyryllium compounds claimed in Japanese Patent Application Publication (JP-B) Nos. 5-13514 and 5-19702 are preferable to be used.

Near IR absorbing dyes defined by the formulas (I) and (II) described in U.S. Pat. No. 4,756,993 are also exemplified as preferable dyes.

Among them, especially preferable dyes are cyanine dyes, phthalocyanine dyes, oxonol dyes, squarylium dyes, pyryllium salts, thiopyryllium dyes, and nickel thiolate complexes. Further, dyes defined by the following general formulas (a) to (e) are preferable since they are excellent in photoelectric conversion efficiency and the cyanine dyes defined by the following general formula (a) are most preferable, in the case of using them in the resin composition of the invention, since they have mutual activity with the aqueous alkaline solution-soluble resin and they are excellent in stability and economical property.

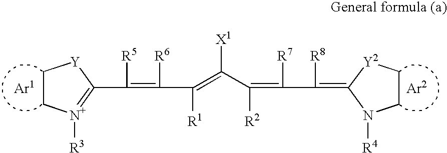

In the general formula (a), X¹ denotes hydrogen, halogen, —NPh₂, X²-L¹ or a group shown as follows: where X² denotes oxygen or sulfur and L¹ denotes C₁₋₁₂ hydrocarbon group, heteroatom-containing aromatic ring, heteroatom-containing C₁₋₁₂ hydrocarbon group: where the heteroatom is N, S, O, halogen, or Se.

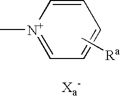

In the above-mentioned formula, Xa⁻ is defined same as Za⁻, which will be described later; R^{a} denotes a substituent group selected from hydrogen, alkyl, aryl, substituted/unsubstituted amino, or halogen.

R¹ and R² independently denote C₁₋₁₂ hydrocarbon group. In terms of storage stability of a photosensitive layer coating solution, R¹ and R² are preferably C_{≦2} hydrocarbon group and further preferably R¹ and R² are bonded with each other to form 5-member or 6-member ring.

Ar¹ and Ar²may be similar or dissimilar to each other and denote substituted/unsubstituted aromatic hydrocarbon group. As a preferable aromatic hydrocarbon group, benzene ring or naphthalene rings are exemplified. Preferable examples of the substituent group are C_{≦12} hydrocarbon group, halogen, and C_{≦12} alkoxyl group. Y¹ and Y² may be similar or dissimilar to each other and denote sulfur or C_{≦12} dialkylmethylene group.

R³ and R⁴ may be similar or dissimilar to each other and denote substituted/unsubstituted C_{≦20} hydrocarbon group. As a preferable substituent group, C_{≦12} alkoxy group, carboxyl group, and sulfo group may be exemplified. R⁵, R⁶, R⁷ and R⁸ may be similar or dissimilar to one another and denote hydrogen or C_{≦12} hydrocarbon group. In terms of availability of the raw material, hydrogen atom is preferable as the substituent.

Za⁻ denotes an anion for pair formation. Incidentally, if a cyanine dye defined by the general formula (a) has an anionic substituent group in the structure and does not require to neutralize the electric charge, Za⁻ is not needed. In terms of storage stability of the photosensitive layer coating solution, Za⁻ is preferably halogen ion, perchlorite ion, tetrfluoroborate ion, hexafluorphosphate ion, and sulfonate ion and more preferably perchlorite ion, hexafluorophosphate ion, and arylsulfonate ion.

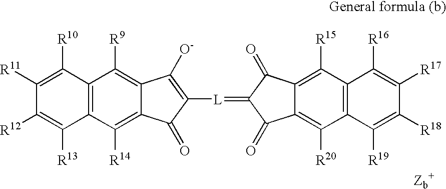

In the general formula (b), L denotes methine chain of 7 or more conjugated carbon atoms and the methine chain may have substituent groups and the substituent groups may be bonded each other to form a cyclic structure. Zb⁺ denotes a cation for pair formation. As apreferable cation for pair formation, ammonium, iodonium, sulfonium, phosphonium, pyridinium, and alkali metal cation (Na⁺, K⁺, Li⁺) can be exemplified.

R⁹ to R¹⁴ and R¹⁵ to R²⁰ independently denote substituent group selected from hydrogen, halogen, cyano group, alkyl group, aryl group, alkenyl group, alkinyl group, carbonyl group, thio group, sulfonyl group, sulfinyl group, oxy group, and amino group or a combination of two or three substituents among them and may form a cyclic structure by being bonded with one another. In the general formula (b), a compound of which L denotes methine chain with 7 conjugated carbon atoms and R⁹ to R¹⁴ and R¹⁵ to R²⁰ all denote hydrogen is preferable in terms of availability and effect.

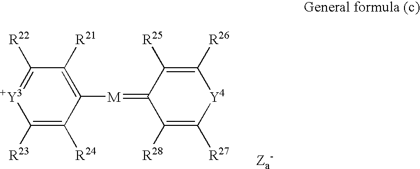

In the general formula (c), Y³ and R⁴independently denote oxygen, sulfur, selenium, or tellurium; M denotes methine chain with 5 or more conjugated carbon atoms; and R²¹ to R²⁴ and R²⁵ to R²⁸ may be similar or dissimilar to one another and independently denote hydrogen, halogen, cyano group, alkyl group, arylgroup, alkenylgroup, alkinylgroup, carbonylgroup, thio group, sulfonyl group, sulfinyl group, oxy group, or amino group. Also, in the formula, Za⁻ denotes an anion for pair formation and can be defined same as Za⁻ in the above-mentioned general formula (a).

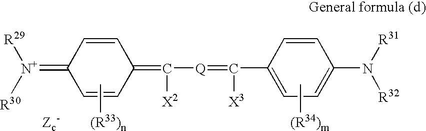

In the general formula (d), R²⁹ to R³¹ independently denote hydrogen, alkyl group, or aryl group; R³³ and R³⁴ independently denote alkyl group, substituted oxy group, or halogen; n and m independently denote an integer of 0 to 4; either R²⁹ and R³⁰ or R³¹ and R³² may be bonded with each other to form a ring or R²⁹ and/or R³⁰ may be bonded with R³³ to form a ring or R³¹ to R³² may be bonded with R³⁴ to form a ring; and further if a plurality of R³³ or R³⁴ exist, R³³ groups or R³⁴ groups may bonded themselves to form a ring; X² and X³ independently denote hydrogen, alkyl or aryl group and at least one of X² and X³ denote hydrogen or aryl group; Q denotes substituted/unsubstituted trimethine or pentamethine and may form a ring structure with a divalent organic group; Zc⁻ denotes an anion for pair formation and can be defined same as Za⁻ in the above-mentioned general formula (a).

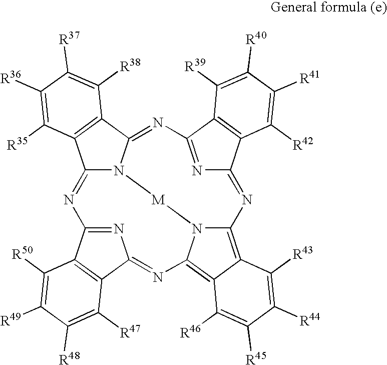

In the general formula (e), R³⁵ to R⁵⁰ independently denote substituted/unsubstituted hydrogen, halogen, cyano group, alkyl group, aryl group, alkenyl group, alkinyl group, hydroxyl group, carbonyl group, thio group, sulfonyl group, sulfinyl group, oxy group, amino group, or onium salt structure; M denotes two hydrogen atoms, metal atom, halometal, or oxymetal wherein the metal atom includes Group IA, IIA, IIIB, IVB from the periodic table, transition metals of the first, second and third cycles, and lanthanides and preferably copper, magnesium, iron, zinc, cobalt, aluminum, titanium, and vanadium among them.

As a pigment to be used as an IR absorbing agent in the invention, commercialized pigments and pigments described in Color Index (C. I.) handbook, “Newest Pigment Handbook” (Japan Pigment Technology Assoc., 1977), “Newest Pigment Application Technology” (CMC Books, 1986) and “Printing Ink Technology” (CMC Books, 1984) can be exemplified.

Examples of the types of the pigments are black pigments, yellow pigments, orange pigments, brown pigments, red pigments, purple pigments, blue pigments, green pigments, phosphor pigments, metal powder pigments, and additionally, polymer-bonded dyes. Practical examples of the pigments are insoluble azo pigments, azolake pigments, condensation azo pigments, chelated azo pigments, phthalocyanine type pigments, anthraquinone type pigments, perylene type pigments, thioindigo type pigments, quinacridone type pigments, dioxazine type pigments, isoindolinone type pigments, quinophthalone type pigments, dyeing lake pigments, azine pigments, nitroso pigments, nitro pigments, natural pigments, phosphor pigments, inorganic pigments, and carbon black. Among these pigments, carbon black is preferable.

These pigments may be used without or with surface treatment. As the surface treatment, a method of surface-coating with resin or wax; a method of depositing a surfactant; and a method of bonding a reactive substance (for example, a silane coupling agent, an epoxy compound, polyisocyanate and the like) to the pigment surface are supposed to be applicable. The above-mentioned surface treatment method is described in “Property and Application of Metal Soap” (Saiwai Shobo), “Printing Ink Technology” (CMC Books, 1984), and “Newest Pigment Application Technology” (CMC Books, 1986).

The particle diameter of the pigments is preferably in a range of 0.01 μm to 10 μm, more preferably in a range of 0.05 μm to 1 μm, and most preferably in a range of 0.1 μm to 1 μm in terms of stability of a pigment dispersion in a photosensitive layer coating solution or uniformity of a photosensitive layer.

As a method for dispersing pigments, a well-known dispersing technique employed in ink production or toner production can be employed. A dispersing apparatus to be employed may be an ultrasonic dispersing apparatus, a sand mill, an attrition apparatus, a pearl mill, a super mill, a ball mill, an impeller, a disperser, a KD mill, a colloid mill, Dyantron, a three-roll mill, a pressure kneader and the like. “Newest Pigment Application Technology” (CMC Books, 1986) contains detailed description.

These pigments or dyes are added in an amount of 0.01 to 50% by mass, preferably 0.1 to 10% by mass, in the total solid matters composing the photosensitive layer in terms of sensitivity and uniformity of the photosensitive layer. In the case of dyes, the amount is especially preferable to be 0.5 to 10% by mass and in the case of pigments, it is especially preferable to be 0.1 to 10% by mass.

The above-mentioned dyes or pigments may be added in a single layer together with other components contained in the photo sensitive layer or in another different layer. In the case of addition to another layer different from other components, it is preferable to add them in a layer neighboring the layer containing a substance which is thermally decomposable and substantially decreases the solubility of a binder resin in the state the substance is not decomposed. The above-mentioned dyes or pigments are preferably contained in the same layer in which the binder resin is contained; however they may be contained in another different layer.

Based on necessity, the photosensitive layer of the invention may contain other components. Other components may include a variety of additives commonly used for the positive type photosensitive composition for IR laser.

For example, in terms of improvement of dissolution inhibition of image area in a developer, substances such as onium salts, o-quinone diazide compounds, aromatic sulfone compounds, and aromati sulfonic acid esters, which are thermally decomposable and substantially decrease the solubility of the aqueous alkaline solution-soluble polymer compounds in the state they are not decomposed, can be exemplified.

The above-mentioned onium salts include diazonium salts, ammonium salts, phosphonium salts, iodonium salts, sulfonium salts, selenium salts, and arsonium salts and among them, diazonium salts are especially preferable and those described in JP-A No. 5-158230 are preferable as the diazonium salts.

The above-mentioned o-quinone diazide compounds include any compounds with various structures if they have one or more o-quinone diazido groups and their alkali-solubility is increased by thermal decomposition. Since o-quinone diazide has both of an effect on a binder resin to lose the dissolution inhibiting function by thermal decomposition and an effect of converting the o-quinone diazide itself into an alkali-soluble substance, it functions as a dissolution promoting agent for the binder. The addition amount of a o-quinone diazide compound is preferably 1 to 50% by mass, more preferably 5 to 30% by mass, and most preferably 10 to 30% by mass in the total solid matters in the photosensitive layer.

Examples of a pair ion of the above-mentioned onium salts are tetrafluoroboric acid, hexafluorophosphoric acid, triisopropylnaphthalenesulfonic acid, 5-nitro-o-toluenesulfonic acid, 5-sulfosalicylic acid, 2,5-dimethylbenzenesulfonic acid, 2,4,6-trimethylbenzenesulfonic acid, 2-nitrobenzenesulfonic acid, 3-chlorobenzenesulfonic acid, 3-bromobenzenesulfonic acid, 2-fluorcaprylnaphthalenesulfonic acid, dodecylbenzenesulfonic acid, 1-naphthol-5-sulfonic acid, 2-methoxy-4-hydroxy-5-benzoyl-benzenesulfonic acid, and p-toluenesulfonic acid. Among them, aromatic alkylsulfonic acid such as hexafluorophosphoric acid, triisopropylnaphthalenesulfonic acid, and 2,5-dimethylbenzenesulfonic acid are preferable.

The addition amount of additives other than the above-mentioned o-quinone diazide compound is preferably 1 to 50% by mass, more preferably 5 to 30% by mass, and furthermore preferably 10 to 30% by mass in the total solid matters in the photosensitive layer.

The additives and the binder are preferably added in a single layer.

In order to further improve the sensitivity, cyclic acid anhydrides such as phthalic anhydride; phenols such as bisphenol A and p-nitrophenol; and organic acids such as p-toluenesulfonic acid and dodecylbenzenesulfonic acid may be added.

The ratio of above-mentioned cyclic acid anhydrides, phenols, or organic acids occupying in the photosensitive layer is preferably 0.05 to 20% by mass, more preferably 0.1 to 15% by mass, and most preferably 0.1 to 10% by mass.

To the photosensitive layer, in order to improve the coatability, a surfactant such as a fluoro type surfactant described in JP-A No. 62-170950 can be added. The content of the surfactant is preferably 0.01 to 1% by mass and more preferably 0.05 to 0.5% by mass in the total solid matters in the photosensitive layer.

As described later, the photosensitive layer is formed by dissolving the respective components composing the layer in a solvent and then applying the obtained solution to a substrate.

(Substrate)

As a substrate for the invention, a plate-like substrate stable in size is preferable and examples of the substrate include paper, paper laminated with plastics (for example, polyethylene, polypropylene, polystyrene, and the like), metal sheets (for example, aluminum, zinc, copper, and the like), plastic films (for example, cellulose diacetate, cellulose triacetate, cellulose propionate, cellulose butyrate, cellulose acetate butyrate, cellulose nitrate, polyethylene terephthalate, polyethylene, polystyrene, polypropylene, polycarbonate, polyvinyl acetal, and the like), and paper and plastic films laminated with above exemplified metals or coated with the metals by evaporation.

As the substrate for the invention, a polyester film or an aluminum sheet is preferable and between them, the aluminum sheet, which has size stability and is relatively economical is especially preferable. A preferable aluminum sheet is a pure aluminum sheet or an alloy sheet containing aluminum as a main component and a trace of different elements and also a plastic film laminated with aluminum by evaporation may be included. The elements contained in the aluminum alloy include silicon, iron, manganese, copper magnesium, chromium, zinc, bismuth, nickel and titanium. The content of each element in the alloy is not higher than 10% by mass. As the aluminum sheet, pure aluminum is preferable, however completely pure aluminum is difficult to be produced in relation to refining technique and therefore other different elements may slightly be contained. In this meaning, the aluminum sheet is not necessarily limited in its composition and conventionally known aluminum sheet materials can properly be utilized. The thickness of the aluminum sheet is preferably 0.1 to 0.6 mm, more preferably 0.15 to 0.4 mm, and furthermore preferably 0.2 to 0.3 mm.

Prior to the surface-roughening of the aluminum sheet, based on necessity, degreasing treatment for removing rolling oil on the surface is carried out using a surfactant, an organic solvent or an aqueous alkaline solution.

The surface-roughening of the aluminum sheet is carried out by a variety of methods and for example, a mechanical surface-roughening method, an electrochemically surface-dissolving and roughening method and chemically surface-dissolving method can be employed to carry out the treatment. As the mechanical method, known methods such as a ball abrading method, a brush abrading method, a blast abasing method and a buff abasing method can be employed. As the electrochemical surface-roughening method, a method carried out in an electrolytic solution such as hydrochloric acid or nitric acid by alternating current or direct current application can be employed.

The aluminum sheet surface-roughened in such a manner is to be subjected to anodization in order to increase the water-retaining property and wear resistance base on necessity after alkali etching treatment or neutralization treatment carried out based on necessity. The ratio of the anodized layer by the anodization is preferably 1.0 g/m². If the ratio of the anodized layer is less than 1.0 g/m², the printing durability becomes insufficient or in the case of using the sheet as planographic printing plate, scratches are easily formed in the non-image portionimage portions and ink adhesion to the scratches at the time of printing, what is called scratch staining, easily occurs in some cases. After the anodization, the surface of the above-mentioned aluminum is subjected to treatment for making the surface hydrophilic based on necessity.

(Resin Intermediate Layer and the Like)

In the planographic printing plate precursor of the invention, based on necessity, a resin intermediate layer may be formed between the photosensitive layer and the substrate.

Formation of the resin intermediate layer makes it possible to form an IR sensible layer (photosensitive layer) whose solubility in an alkaline developer is improved by exposure in the exposure face or in the vicinity of the face, so that the sensitivity to IR laser is further improved. Also, if the resin intermediate layer of a polymer is formed between the substrate and the IR sensible layer, the resin intermediate layer is made easy to function as a heat insulating layer and therefore, the formation brings a desirable effect that the heat generated by exposure by IR laser is not diffused and efficiently utilized for the image formation to result in high sensitivity.

Further, in the non-exposed parts, it is supposed that the photosensitive layer itself, which is non-penetrable with alkaline developer, functions as a protection layer for the resin intermediate layer to stabilize the development form images with excellent discrimination and assure the stability with the lapse of time.

Since the resin intermediate layer is composed as a layer containing an alkali-soluble polymer as a main component and has good solubility in the developer, formation of such a resin intermediate layer adjacently to the substrate makes it possible to quickly remove the exposed parts without leaving a residual film in the case of dissolution and diffusion of the components of the photosensitive layer, whose dissolution inhibiting function is released by exposure, in the developer even if the developer with deteriorated activity is used. That is supposed to contribute to the improvement of the developability. Because of the above-mentioned reasons, the resin intermediate layer is supposed to be useful.

As described above, the resin intermediate layer is composed as a layer containing the alkali-soluble polymer as a main component, in order to make the boundary between a recording layer and the resin intermediate layer clear, the alkali-soluble resin to be employed for the intermediate layer is preferably different from the alkali-soluble resin to be employed for the recording layer.

Further, in the planographic printing plate precursor of the invention, another layer such as an undercoat layer may be formed based on necessity besides the above-mentioned photosensitive layer and the resin intermediate layer.

(Production of the Planographic Printing Plate Precursor)

The photosensitive layer of the planographic printing plate precursor can be formed by dissolving components for a coating solution in a solvent and applying the solution to a proper substrate and drying it. Another layer to be formed based on necessity can also be formed in the same manner as that for the photosensitive layer.

The solvent to be used for the coating solution may include ethylene dichloride, cyclohexanone, methyl ethyl ketone, methanol, ethanol, propanol, ethylene glycol monomethyl ether, 1-methoxy-2-propanol, 2-methoxyethyl acetate, 1-methoxy-2-propylacetate, dimethoxyethane, methyl lactate, ethyl lactate, N,N-dimethylacetamide, N,N-dimethylformamide, tetramethylurea, N-methylpyrrolidone, dimethyl sulfoxide, sulflan, γ-butyrolactone, toluene, and the like, however it is not limited to these examples. These solvents are used alone or in form of mixtures. The concentration of the above-mentioned components (in total solid matters including additives) in the solvent is preferably 1 to 50% by mass.

The coating amount (solid matters) on the substrate obtained after application and drying differs depending on the use, however in terms of the sensitivity and coatability of the photosensitive layer, generally it is preferably 0.5 to 5.0 g/m².

As the application method, a variety of methods can be employed and, for example, bar coater coating, rotation coating, spraying coating, curtain coating, dip coating, air-knife coating, blade coating, and roll coating can be exemplified.

In addition, a surfactant, for example fluoro type surfactants described in JP-A No. 62-170950 may be added to the photosensitive layer. The addition amount of such surfactants is preferably 0.01 to 1% by mass and more preferably 0.05 to 0.5% by mass in the total solid matters in the photosensitive layer.

(Exposure, Development Treatment)

The positive planographic printing plate precursor produced in the above-mentioned manner is generally subjected to imagewise exposure and development treatment.

The light source of activation light beam to be employed for the exposure light is preferably those having light emission wavelength in near IR region to IR region and solid state laser and semiconductor laser are especially preferable.

As the developer or the replenishing solution to be used for the development treatment, a conventionally known aqueous alkaline solution can be used. Examples of the solute of the solution are inorganic alkali salts such as silicates of sodium and calcium; tertiary phosphates of sodium, potassium and ammonium; secondary phosphates of sodium, potassium and ammonium; carbonates of sodium, potassium and ammonium; hydrogen carbonates of sodium, potassium and ammonium; borates of sodium, potassium and ammonium; and hydroxides of sodium, ammonium, potassium and lithium; organic alkali agents such as monomethylamine, dimethylamine, trimethylamine, monoethylamine, diethylamine, triethylamine, monoisopropylamine, diisopropylamine, triisopropylamine, n-butylamine, monoethanol amine, diethanol amine, triethanol amine, monoisopropanol amine, diisopropanol amine, ethyleneimine, ethylenediamine, and pyridine. These aqueous alkaline solutions may be used alone or in combination of two or more of them.

Among these aqueous alkaline solutions, an aqueous solution of a silicate such as sodium silicate or potassium silicate is particularly preferable. The reason for that is because the developability can be adjusted depending on the ratio and the concentration of the silicon oxide (SiO₂), a component of the silicate, and an alkali metal oxide (M₂O) and preferable examples are alkali metal silicates described in JP-A No. 54-62004 and JP-B No. 57-7427.

In the case development is carried out by using an automatic developing apparatus, addition of an aqueous solution (a replenishing solution) with a higher alkalinity than that of the developer makes it possible to carry out good treatment of a larger quantity of PS plates without replacing the developer in a development tank for a long duration.

For the purpose of promotion or suppression of developability, dispersion of development scum, or improvement of ink-philicity of image portion of a printing plate, the developer or the replenishing solution may further be mixed with a variety of surfactants and organic solvents based on the necessity. Preferable examples of the surfactants are anionic, cationic, nonionic and amphoteric surfactants. Further, reducing agents such as hydroquinone, resorcin, and inorganic acid salts such as sodium and potassium sulfites and hydrogensulfites; organic carboxylic acids; defoaming agents; and hard water softening agents may be added to the developer and the replenishing solution.

The planographic printing plate subjected to the development treatment by the developer and the replenishing solution is subjected to post-treatment with washing water, a rinsing solution containing a surfactant, and a desensitizing solution containing gum arabi and starch derivative. The post-treatment may be carried out by variously combining the treatment steps.

Recently, in order to make the plate-making process rational and standardize the process in plate-making and printing industries, an automatic developing apparatus for a printing plate has been used widely. The automatic developing apparatus generally comprises a development part and a post-treatment part and is provided with a unit for transporting a printing plate, respective treatment tanks, and a spraying unit and carries out development treatment by spraying respective treatment solutions pumped up by pumps while horizontally transporting an already exposed printing plate. Today, a method for treating a printing plate by immersing and transporting the printing plate by guide rolls in the solution in a treatment solution tank filled with a treatment solution has been known. In such automatic treatment, treatment is carried out simultaneously with supplying replenishing solutions to the respective treatment solutions depending on the treatment quantity and operation duration.

Further, treatment with a practically unused treatment solution, what is called disposable treatment, is also employed.

Planographic printing plates with stable quality can continuously be obtained by applying the image evaluation method and the quality control method of the invention to such development process.

In the case there are unnecessary image portions (for example, the film edge remaining of an original image film) in the planographic printing plate obtained by imagewise exposure and development of a planographic printing plate precursor and successively water washing and/or rinsing and/or gumming, the unnecessary image portions are removed. Such removal is preferably carried out by applying a removal solution as described in JP-B No. 2-13293 to the unnecessary image portions, keeping them as they are for a predetermined duration and then washing with water. Also, a method carried out by developing after radiating active light beam led through an optical fiber described in JP-A No. 59-174842 to the unnecessary image portions can be employed.

The obtained planographic printing plate is supplied to a printing step after application of desensitizing gum based on necessity and if the printing durability of the planographic printing plate is further needed improvement, burning treatment is carried out.

The planographic printing plate obtained through these steps is subjected to an off-set printing apparatus or the like and used for printing a large number of printings.

### EXAMPLES

Hereinafter, the invention will be described along with examples, however it is not intended that the invention be limited to the following examples.

### Example 1

[Production of Planographic Printing Plate Precursor 1]

[Synthesis of Specific Copolymer 1]

Methacrylic acid 31.0 g (0.36 mole), ethyl chloroformate 39.1 g (0.36 mole) and acetonitrile 200 ml were loaded into a three neck distillation flask with 500 ml capacity provided with a stirrer, a cooling pipe, and a dropping funnel and the mixture was stirred while being cooled in an ice bath. Triethylamine 36.4 g (0.36 mole) was dropwise added to the mixture through the dropping funnel in about 1 hour. On completion of addition of Triethylamine, the ice bath was removed and the mixture was stirred at a room temperature for 30 minutes.

To the reaction mixture, p-aminobenzenesulfonamide 51.7 g (0.30 mole) was added and the obtained mixture was stirred for 1 hour while being heated at 70° C. in an oil bath. On completion of reaction, the mixture was thrown to water 1 L while the water was stirred and the mixture was stirred for 30 minutes. The obtained precipitate was separated by filtering the mixture and mixed with water 500 ml to obtain a slurry. A solid was obtained by filtering the slurry. The obtained solid was dried to obtain a while solid of N-(p-aminosulfonylphenyl)methacrylamide (46.9 g yield).

Next, N-(p-aminosulfonylphenyl)methacrylamide 4.61 (0.0192 mole), ethyl methacrylate 2.94 g (0.0258 mole), acrylonitrile 0.80 g (0.015 mole), and N,N-dimethylacetamide 20 g were loaded into a three neck distillation flask with 20 ml capacity provided with a stirrer, a cooling pipe, and a dropping funnel and the mixture was stirred while being heated at 65° C. in a hot water bath. To the mixture, as a polymerization initiator, 2,2′-azobis(2,4-dimethylvaleronitrile) (trade name: “V-65” manufactured by Wako Pure Chemical Industries, Ltd.) 0.15 g was added and while being kept at 65° C., the mixture was stirred under nitrogen current for 2 hours. To the reaction mixture, a mixture containing N-(p-aminosulfonylphenyl)methacrylamide 4.61, ethyl methacrylate 2.94 g, acrylonitrile 0.80 g, N,N-dimethylacetamide, and “V-65” 0.15 g was dropwise added in 2 hours through the dropping funnel. On completion of the addition, the obtained mixture was stirred at 65° C. for 2 hours. On completion of the reaction, methanol 40 g was added to the mixture and the mixture was cooled and then the mixture was thrown to water 2 L while the water was stirred. After the obtained mixture was stirred for 30 minutes, the formed precipitate was separated by filtration and dried to obtain a white solid. The weight average molecular weight (on the basis of polystyrene standards) of the resulting specific copolymer 1 was measured by gel permeation chromatography, which was 53,000.

[Production of Substrate]

After a 0.3 mm thick aluminum plate (grade 1050) was washed with trichloroethylene and degreased, the surface of the plate was roughened by using a nylon brush and a 400 mesh Pumice-water dispersion and well washed with water. The plate was etched by immersing it in a 25% aqueous sodium hydroxide solution at 45° C. for 9 seconds, washed with water, and immersed in 20% nitric acid for 20 seconds and washed with water. The etching extent of the roughened surface was about 3 g/m². Next, the aluminum plate was coated with an anodized layer of 3 g/m² by direct current application with 15 A/dm² current density in a 7% sulfuric acid and washed with water and dried. The resulting plate was treated with an aqueous solution of 2.5% by mass of sodium silicate at 30° C. for 10 seconds and coated with an undercoating solution 1 with the following composition and the coating was dried at 80° C. for 15 seconds to obtain a substrate. The coating thickness of the undercoating layer was 15 mg/M² after the drying.

<Undercoating solution 1>

| | |
|---|---|
| The following copolymer | 0.3 g |
| with 280,000 molecular weight | |
| Methanol | 100 g |
| Water | 1 g |

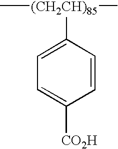

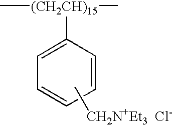

Molecular weight 280,000

The following photosensitive solution 1 was adjusted. The obtained substrate was coated with the photosensitive solution 1 so as to form a coating with a coating thickness of 1.3 g/m² and obtain a planographic printing plate precursor 1.

[Photosensitive Solution 1]

| | |
|---|---|
| Fluorine-containing polymer | 0.03 g |
| (the structure shown below) | |
| The specific copolymer 1 | 0.75 g |
| m, p-cresol novolak | 0.25 g |
| (m/p ratio = 6/4, weight average | |
| molecular weight 3,500, | |
| containing 0.5% by mass of unrelated cresol) | |
| p-toluenesulfonic acid | 0.003 g |
| Tetrahydrophthalic anhydride | 0.03 g |
| Cyanine dye A (the following structure) | 0.017 g |
| Dye obtained as Victoria Pure Blue BOH | 0.015 g |
| having 1-naphthalenesulfonic acid anion | |
| as pair formation ion | |
| 3-methoxy-4- | 0.02 g |
| diazodiphenylaminehexafluorophosphoric acid salt | |
| Fluorine type surfactant | 0.05 g |
| (Megafac F-177, manufactured by | |
| Dainippon Ink and Chemicals, Inc.) | |
| γ-butyrolactone | 10 g |
| Methyl ethyl ketone | 10 g |
| 1-methoxy-2-propanol | 8 g |

Cyanine dye A

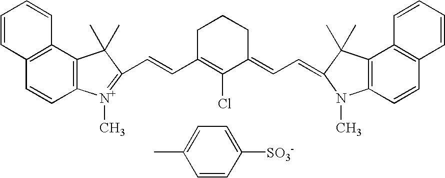

Fluorine-containing polymer

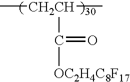

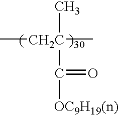

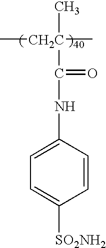

In the obtained planographic printing plate precursor 1 (650 mm×550 mm×0.3 mm thickness), the peripheral part of an actual image, that is the portion to be cut and discarded on completion of printing matter formation, was exposed in the condition that formed checkerboard image with each rectangle size of 7 mm (one side length: 10.6 μm) by using a plate setter (trade name: Luxcel Platesetter 9000 CTP, output 270 mW, rotation speed 1, 000 rpm, resolution 2438 dpi, manufactured by Fuji Photo Film Co., Ltd.).

[Developer]

The planographic printing plate precursor 1 was developed as follows after the exposure.

An alkaline developer A (pH about 13) with the following composition 20 L was loaded into a development treatment tank of a commercialized automatic developing apparatus LP-940H (manufactured by Fuji Photo Film Co., Ltd.) comprising an immersion type developing tank and kept at 30° C. Tap water 8 L was loaded into the second bath of the LP-940H and 8 L of a finishing gum solution containing FP-2W (manufactured by Fuji Photo Film Co., Ltd.) diluted with water at FP-2W:water=1:1 was loaded into the third bath.

<Composition of Alkaline Development Solution A>

| | |
|---|---|
| D sorbitol | 2.5% by mass |
| Sodium hydroxide | 0.85% by mass |
| Diethylenetriamine- | 0.05% by mass |
| pentamethylenephosphonic | |
| acid pentasodium salt | |
| Water | 96.6% by mass |

The development treatment was carried out for the planographic printing plate precursor 1 after the exposure while a developer replenishing solution B with the following composition was supplied, with setting the control impedance value of the development replenishment built in the automatic developing apparatus LP-940H at 40.5 ms/cm.

<Composition of Development Replenishing Solution B>

| | |
|---|---|
| D sorbitol | 5.6% by mass |
| Sodium hydroxide | 2.5% by mass |
| Diethylenetriamine- | 0.2% by mass |
| pentamethylenephosphonic | |
| acid pentasodium salt | |
| Water | 91.7% by mass |

Exposure/development treatment of 100 sheets per a day was carried out continuously for 3 months.

During the execution period, image evaluation was carried out every day by employing the image evaluation method of the invention and the obtained evaluation results were fed back to the exposure/development step to adjust the exposure/development condition and control the quality.

The adjustment of the exposure/development condition in the example was carried out by changing the exposure condition (exposure dose) when the density of the checkerboard image by the planographic printing plate developed by a subject developer (subject sample) differed from that of planographic printing plate developed by the standard developer (the standard sample) by 0.1 or higher.

As the standard sample, the plate produced at the first day of the test period was employed. The density of the checkerboard image at the first day was 0.9.

As the subject sample, a first plate produced on each day of the test duration in the same conditions (or adjusted conditions if the exposure/development condition was adjusted) as in producing the above-mentioned standard sample was used.

The density of the checkerboard image was measured for a predetermined surface area in the region where the checkerboard image was formed by a reflection densitometer (D19C type) manufactured by GRETAG company (the following example 2 and example 3 were same).

The details of the quality control were as follows.

Since the density of the checkerboard image was decreased to 0.78 at 15th day, the feedback was carried out based on the control method of the invention and the set exposure dose was changed to be 216 mW to increase the density of the checkerboard image to 0.90.

Since the density of the checkerboard image was increased to 1.02 at 35th day, the feedback was carried out based on the control method of the invention and the set exposure dose was changed to be 270 mW to suppress the density of the checkerboard image to 0.90.

After that, stable development state was kept to the 90th day (for 3 months).

As described above, development treatment could be carried out stably for 90 days by employing the image evaluation method and the quality control method of the invention.

Incidentally, since the density of the checkerboard image was decreased lower than the initial set value at 15th day, it is understood that, if the control method of the invention had not been employed, the automatic developing apparatus would have remained in a satisfactory condition under which a desirable planographic printing plate can be obtained, only for 15 days. From this results, it is understood that the image evaluation method and the quality control method of the invention are significantly effective.

### Example 2

[Production of Planographic Printing Plate Precursor 2]

[Production of Substrate]

After a 0.24 mm thick aluminum plate (grade 1050) was washed with trichloroethylene and degreased, the surface of the plate was roughened by using a nylon brush and a 400 mesh Pumice-water dispersion and well washed with water. The plate was etched by immersing it in a 25% aqueous sodium hydroxide solution at 45° C. for 9 seconds, washed with water, and immersed in 20% nitric acid for 20 seconds and washed with water. The etching extent of the roughened surface was about 3 g/m². Next, the aluminum plate was coated with an anodized layer of 3 g/m² by direct current application with 15 A/dm² current density in a 7% sulfuric acid and washed with water and dried. The resulting plate was treated with an aqueous solution of 2.5% by mass of sodium silicate at 30° C. for 10 seconds and coated with an undercoating solution with the following composition and the coating was dried at 80° C. for 15 seconds to obtain a substrate. The coating thickness of the undercoating layer was 15 mg/m² after the drying.

<Undercoating Solution 1>

| | |
|---|---|
| The above-mentioned copolymer | 0.3 g |
| with 280,000 molecular weight | |
| Methanol | 100 g |
| Water | 1 g |

The obtained substrate was coated with the photosensitive solution 2 with the following composition so as to form a coating with a coating thickness of 1.8 g/m² and obtain a planographic printing plate precursor 2.

[Photosensitive Solution ]2

| | |
|---|---|
| m, p-cresol novolak | 1.0 g |
| (m/p ratio = 6/4, | |
| weight average molecular weight 8,000, | |
| containing 0.5% by mass of un-reacted cresol) | |
| Pyryllium salt dye B | 0.1 g |
| (the structure shown below) | |
| Phthalic anhydride | 0.05 g |
| p-toluenesulfonic acid | 0.002 g |
| Ethyl Violet having | 0.02 g |
| 6-hydroxy-β-naphthalenesulfonic acid | |
| as a counter ion | |
| Fluorine type surfactant | 0.05 g |
| (Megafac F-177, manufactured by | |
| Dainippon Ink and Chemicals, Inc.) | |
| Methyl ethyl ketone | 8 g |
| 1-methoxy-2-propanol | 4 g |

Pyryllium salt dye B

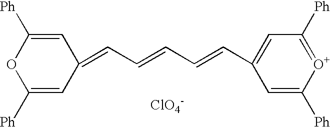

[Exposure]

In the obtained planographic printing plate precursor 2 (650 mm×550 mm×0.24 mm thickness), the peripheral part of an actual image, that is the portion to be cut and discarded on completion of printing matter formation, was exposed in the condition that formed checkerboard image with each rectangle size of 7 mm (one side length: 10.6 μm) by using a plate setter (trade name: Trendsetter 3244F, output 9.0 W, rotation speed 150 rpm, resolution 2400 dpi, manufactured by Creo Inc.)

[Developer]

The planographic printing plate precursor 2 was developed as follows after the exposure.

An alkaline developer C (pH about 13) with the following composition 20 L was loaded into a development treatment tank of a commercialized automatic developing apparatus LP-940H (manufactured by Fuji Photo Film Co., Ltd.) comprising an immersion type developing tank and kept at 30° C. Tap water 8 L was loaded into the second bath of the LP-940H and 8 L of a finishing gum solution containing FP-2W (manufactured by Fuji Photo Film Co., Ltd.) diluted with water at FP-2W : water=1:1 was loaded into the third bath.

<Composition of Alkaline Development Solution C>

| | |
|---|---|
| SiO₂—K₂O (K₂O/SiO₂ = 1/1 by mole) | 4.0% by mass |
| Citric acid | 0.5% by mass |
| Polyethylene glycol | 0.5% by mass |
| (weight average molecular weight = 1,000) | |
| Water | 95.0% by mass |

The development treatment was carried out for the planographic printing plate precursor 2 (650 mm×550 mm×0.24 mm thickness) after the exposure while 35 cc of a developer replenishing solution D with the following composition was supplied for every one plate development by LP-940H.

<Composition of Development Replenishing Solution D>

| | |
|---|---|
| SiO₂—K₂O (K₂O/SiO₂ = 1/1 by mole) | 5.0% by mass |
| Citric acid | 0.6% by mass |
| Polyethylene glycol | 0.6% by mass |
| (weight average molecular weight = 1,000) | |
| Water | 93.8% by mass |

Exposure/development treatment of 50 sheets per a day was carried out continuously for 90 days.

During the execution period, image evaluation was carried out every day by employing the image evaluation method of the invention and the obtained evaluation results were fed back to the exposure/development step to adjust the exposure/development condition and control the quality.

The adjustment of the exposure/development condition in the example was carried out by changing the exposure condition (exposure dose) when the density of the checkerboard image of an subject sample differed from that of checkerboard image of the standard sample by 0.1 or higher.

As the standard sample, the plate produced at the first day of the test period was employed. The density of the checkerboard image at the first day was 0.85.

As the subject sample, a plate produced on each day during the test duration in the same conditions (or adjusted conditions if the exposure/development condition was adjusted) as in producing the above-mentioned standard sample was used.

The details of the quality control were as follows.

Since the density of the checkerboard image was increased to 0.97 at 15th day, the feedback was carried out based on the control method of the invention and the set exposure dose was changed to be 10.5 W to decrease the density of the checkerboard image to 0.85.

Since the density of the checkerboard image was decreased to 0.73 at 45th day, the feedback was carried out based on the control method of the invention and the set exposure dose was changed to be 8.0 W to increase the density of the checkerboard image to 0.85.

After that, stable development state was kept to the 90th day.

As described above, development treatment could be carried out stably for 90 days by employing the image evaluation method and the quality control method of the invention.

Incidentally, since the density of the checkerboard image was decreased lower than the initial set value at 15th day, it is understood that, if the control method of the invention had not been employed, the automatic developing apparatus would have remained in a satisfactory condition under which a desirable planographic printing plate can be obtained, only for 15 days. From this results, it is understood that the image evaluation method and the quality control method of the invention are significantly effective.

### Example 3

A planographic printing plate precursor 3 produced in the same manner as Example 2 and an automatic developing apparatus and a developer same as those used in Example 2 were employed.

In the obtained planographic printing plate precursor 3 (1030 mm×800 mm×0.30 mm thickness), the peripheral part of an actual image was exposed in the condition that formed checkerboard image with one side length of 10.6 μm by using a plate setter manufactured by Creo Inc. (trade name: Trendsetter 3244F, output 9.0 W, rotation speed 150 rpm, resolution 2400 dpi) and then developed.

Exposure/development treatment of 40 sheets per a day was carried out continuously for 90 days.

During the execution period, image evaluation was carried out every day by employing the image evaluation method of the invention and the obtained evaluation results were fed back to the exposure/development step to adjust the exposure/development condition and control the quality.

The adjustment of the exposure/development condition in the example was carried out by changing the exposure condition (exposure dose) when the density of the checkerboard image of an subject sample differed from that of the checkerboard image of the standard sample by 0.1 or higher.

As the standard sample, the plate produced at the first day of the test period was employed. The density of the checkerboard image at the first day was 0.85.

As the subject sample, a plate produced on each day during the test duration in the same conditions (or adjusted conditions if the exposure/development condition was adjusted) as in producing the above-mentioned standard sample was used.

The details of the quality control were as follows.

Since the density of the checkerboard image was decreased to 0.73 at 10th day, the development duration was changed to be 10.5 seconds from 12 seconds to result in 0.85 density of the checkerboard image.

Since the density of the checkerboard image was decreased to 0.73 at 18th day, the development temperature was changed to be 28.5° C. from 30.0° C. to result in 0.85 density of the checkerboard image.

Since the density of the checkerboard image was increased to 0.97 at 30th day, the development duration was changed to be 12 seconds from 10.5 seconds to result in 0.85 density of the checkerboard image.

Since the density of the checkerboard image was increased to 0.97 at 46th day, the development temperature was changed to be 30° C. from 28.5° C. to result in 0.85 density of the checkerboard image.

After that, stable development state was kept to the 90th day.

As described above, development treatment could be carried out stably for 90 days by employing the image evaluation method and the quality control method of the invention.

Incidentally, since the density of the checkerboard image was decreased lower than the initial set value at 15th day, it is understood that, if the control method of the invention had not been employed, the automatic developing apparatus would have remained in a satisfactory condition under which a desirable planographic printing plate can be obtained, only for 15 days. From this results, it is understood that the image evaluation method and the quality control method of the invention are significantly effective.

Accordingly, the invention can provide a simple image evaluation method of a planographic printing plate for easily determining plate-making conditions, particularly the active state of a developer, of a positive planographic printing plate precursor for IR laser for direct plate-making.

Further, the invention can provide a quality control method of a planographic printing plate for keeping the quality of a planographic printing plate constant and continuously forming uniform images, in which feedback of the results obtained by the above-mentioned image evaluation method to the exposure/development step is carried out.

What is claimed is:

1. An image evaluation method for a planographic printing plate comprising:
producing a standard developer-treated planographic printing plate by preparing a planographic printing plate precursor comprising a substrate and a photosensitive layer, which includes an aqueous alkaline solution-soluble resin and a compound that absorbs light and generates heat, the photosensitive layer being provided on the substrate, exposing the planographic printing plate precursor to form a checkerboard image of rectangles having one side that is 5 to 50 μm in length, and then developing the image with a standard developer;
producing a subject developer-treated planographic printing plate by preparing a planographic printing plate precursor comprising a substrate and a photosensitive layer including an aqueous alkaline solution-soluble resin and a compound that absorbs light and generates heat, the photosensitive layer being provided on the substrate, exposing the planographic printing plate precursor to form a checkerboard image of rectangles having one side that is 5 to 50 μm in length, and then developing the image with a developer to be evaluated; and
comparing the checkerboard image resulted from the standard developer-treated planographic printing plate, with that resulted from the subject developer-treated planographic printing plate.

2. The image evaluation method of claim 1, wherein producing a standard developer-treated planographic printing plate comprises forming the checkerboard image portion in a peripheral portion of a desired image portion, the peripheral portion corresponding to a portion of a printed matter to be cut and discarded after printing is completed.

3. The image evaluation method of claim 1, wherein the planographic printing plate precursor is a positive planographic printing plate precursor for use with an IR laser.

4. The image evaluation method of claim 1, wherein the length of one side of the rectangles composing the checkerboard images is the length of one side of a minimum pixel unit.

5. The image evaluation method of claim 1, wherein comparing the checkerboard images comprises comparing the density of the checkerboard image resulted from the standard developer-treated planographic printing plate with the density of the checkerboard image resulted from the subject developer-treated planographic printing plate.

6. An image evaluation method for a planographic printing plate comprising:
producing a planographic printing plate precursor having a substrate and a photosensitive layer, which includes an aqueous alkaline solution-soluble resin and a compound that absorbs light and generates heat, the photosensitive layer being provided on the substrate;
exposing the planographic printing plate precursor under conditions that form a checkerboard image composed of rectangles having one side which is a length of minimum pixel unit;
producing a standard developer-treated planographic printing plate by developing the exposed precursor with a standard developer;
producing a subject developer-treated planographic printing plate by developing the exposed precursor with a developer to be evaluated, namely, a subject developer; and
comparing the density of the checkerboard image resulted from the standard developer-treated planographic printing plate, with the density of the checkerboard image resulted from the subject developer-treated planographic printing plate.

7. The image evaluation method of claim 6, wherein exposing the planographic printing plate precursor comprises forming the checkerboard image portion in a peripheral portion of a desired image portion, the peripheral portion corresponding to a portion of a printed matter to be cut and discarded after printing is completed.

8. The image evaluation method of claim 6, wherein the planographic printing plate precursor is a positive planographic printing plate precursor for use with an IR laser.

9. The image evaluation method of claim 6, wherein the length of the one side of the rectangles composing the checkerboard image is 5 to 50 μm.

10. A quality control method for a planographic printing plate, the method comprising the steps of:
(A) producing a standard developer-treated planographic printing plate by preparing a planographic printing plate precursor having a substrate and a photosensitive layer, which includes an aqueous alkaline solution-soluble resin and a compound that absorbs light and generates heat, disposed on the substrate, exposing the planographic printing plate precursor under conditions that form a checkerboard image composed of rectangles having one side that is 5 to 50 μm in length, and then developing the image with a standard developer;
(B) producing a subject developer-treated planographic printing plate in the same manner as in the step (A), except that the development is carried out with a developer to be evaluated;
(C) comparing the checkerboard images resulted from the standard developer-treated planographic printing plate, with that resulted from the subject developer-treated planographic printing plate; and
(D) adjusting the exposure/development conditions when a difference between the density of the checkerboard image resulted from the standard developer-treated planographic printing plate and that resulted from the checkboard image of the subject developer-treated planographic printing plate is found out to be at least a predetermined value, based on the result of the comparison.

11. The quality control method for aplanographic printing plate of claim 10, wherein the method further comprises a step of (E) producing a planographic printing plate in a manner similar to that of the step (B) but under adjusted exposure/development conditions after completing the step (D), and the steps (E), (C), and (D) are carried out in this order at least one time or multiple times.

12. The quality control method for aplanographic printing plate of claim 10, wherein the step (D) of adjusting exposure/development condition comprises at least one of a step of increasing the exposure condition and a step of activating the development condition, when the density of the checkerboard image resulted from the subject developer-treated planographic printing plate is higher than the density of the checkerboard image resulted from the standard developer-treated planographic printing plate by at least a predetermined value and it is determined that activity of the developer has decreased.

13. The quality control method for aplanographic printing plate of claim 10, wherein the step (D) of adjusting exposure/development condition comprises at least one of a step of decreasing the exposure condition and a step of moderating development conditions, when the density of the checkerboard image in the subject developer-treated planographic printing plate is lower than that of the checkerboard image in the standard developer-treated planographic printing plate by at least a predetermined value and it is determined that activity of the developer is excessive.

14. The quality control method for aplanographic printing plate of claim 10, wherein the step (A) of producing the standard developer-treated planographic printing plate comprises a step of forming the checkerboard image portion in a peripheral portion of a desired image portion, the peripheral portion corresponding to a portion of a printed matter to be cut and discarded after printing is completed.

15. A quality control method for a planographic printing plate, the method comprising the steps of:
(a) preparing a planographic printing plate precursor comprising a substrate and a photosensitive layer, which contains an aqueous alkaline solution-soluble resin and a compound that absorbs light and generates heat, the photosensitive layer being disposed on the substrate;
(b) exposing the planographic printing plate precursor under a condition that forms a checkerboard image composed of rectangles having one side be a length that is a length of minimum pixel unit;
(c) producing a standard developer-treated planographic printing plate by developing the exposed precursor with a standard developer;
(d) producing a subject developer-treated planographic printing plate by developing the exposed precursor with a subject developer to be evaluated, which is a subject developer;
(e) comparing the density of the checkerboard image resulted from the standard developer-treated planographic printing plate, with the density of the checkerboard image resulted from the subject developer-treated planographic printing plate; and
(f) adjusting exposure/development conditions when the difference between the density of the checkerboard images resulted from the standard developer-treated planographic printing plate and that of the checkboard images resulted from the subject developer-treated planographic printing plate is turned out to be at least a predetermined value based on the result of the comparisson.

16. The quality control method for aplanographic printing plate of claim 15, wherein the method further comprises a step of: (g) carrying out the steps (e) and (f) by using a planographic printing plate produced by carrying out steps (b), (c), and (d) under the adjusted exposure/development conditions after completing the step (f).

17. The quality control method for a planographic printing plate of claim 15, wherein the step (f) of adjusting exposure/development condition comprises at least one of a step of increasing the exposure condition and a step of activating the development condition, when the density of the checkerboard image resulted from the subject developer-treated planographic printing plate is higher than the density of the checkerboard image resulted from the standard developer-treated planographic printing plate by at least a predetermined value and it is determined that activity of the developer has decreased.

18. The quality control method for a planographic printing plate of claim 15, wherein the step (f) of adjusting exposure/development condition comprises at least one of a step of decreasing the exposure condition and a step of moderating development conditions when the density of the checkerboard image resulted from the subject developer-treated planographic printing plate is lower than the density of the checkerboard image resulted from the standard developer-treated planographic printing plate by at least a predetermined value and it is determined that activity of the developer has increased.

19. The quality control method for a planographic printing plate of claim 15, wherein the exposure step (b) comprises a step of forming the checkerboard image portion in a peripheral portion of a desired image portion, the peripheral portion corresponding to a portion of a printed matter to be cut and discarded after printing is completed.

20. The quality control method for a planographic printing plate of claim 15, wherein a length of one side of the rectangular shapes composing the checkerboard images is 5 to 50 μm.
